(19) United States
(12) Patent Application Publication
(10) Pub. No.: US 2002/0171138 A1
(43) Pub. Date: Nov. 21, 2002

(54) Multilayer wiring board and semiconductor device

(76) Inventors: Yasuo Osone, Chiyoda (JP); Norio Nakazato, Kashiwa (JP); Isao Oobu, Sagamihara (JP); Kiichi Yamashita, Shiroyama (JP); Shinji Moriyama, Komoro (JP); Takayuki Tsutsui, Komoro (JP); Mitsuaki Hibino, Komoro (JP); Chushiro Kusano, Niiza (JP); Yasunari Umemoto, Sayama (JP)

Correspondence Address: ANTONELLI TERRY STOUT AND KRAUS, SUITE 1800, 1300 NORTH SEVENTEENTH STREET, ARLINGTON, VA, 22209

(21) Appl. No.: 09/943,512

(22) Filed: Aug. 31, 2001

(30) Foreign Application Priority Data
May 21, 2001 (JP) 2001-150260

(51) Int. Cl. H01L 23/34

(52) U.S. Cl. 257/712

(57) ABSTRACT

A multilayer wiring board having board having through holes in a thickness-wise direction, in which wiring board a semiconductor substrate mounted on the multi-layer wiring board has through holes in a thickness-wise direction, and entire areas, which the through holes in the semiconductor substrate occupy, in a plane orthogonal to the thickness-wise direction of the multilayer wiring board and of the semiconductor substrate are included in areas, which the through holes in the multilayer wiring board occupy.

### BACKGROUND OF THE INVENTION

The present invention relates to a semiconductor device such as a multifinger type device used in high-frequency power amplifiers for portable communication terminal.

Power enabling communication from a position distant from a communication relay point is required of portable communication terminals such as portable telephones, and thus high-frequency power amplifiers in portable communication terminals have been increased in capacity.

As a measure for increasing high-frequency power amplifiers in capacity, it is possible to provide an increase in current for high output by modularizing and arranging many bipolar transistors (hereafter, referred to as transistors) in parallel at predetermined spacing.

However, if transistors are arranged in parallel at predetermined spacing, centrally positioned transistors are thermally affected by adjacent transistors to become highest in thermal resistance (hereinafter referred to as calorific value).

In this manner, when transistors having high calorific values are present among transistors arranged in parallel, current flows through transistors of high calorific values in a concentrated manner, and hence the transistors possibly cause thermorunaway to be broken.

Therefore, it is conventional that transistors are varied in size according to calorific values thereof.

In addition, this kind of conventional technique is disclosed in, for example, Japanese Patent Unexamined Publication Nos. 2-219298 and 5-152340.

In recent years, it has been increasingly demanded to make portable communication terminals small in size, lightweight, and low in cost, as well as to increase power amplifiers in power, as mentioned above. As matters stand, it is naturally inevitable to miniaturize power amplifiers.

Thereupon, when transistors themselves are made small in order to miniaturize a power amplifier, it is found that heating temperature of transistors disposed on ends of a row of transistors arranged in parallel is high. The reason for this is believed to be that while heat generated in centrally positioned transistors is transferred and diffused to adjacent transistors, heat transfer is small in endwise positioned transistors to cause an increase in calorific value since there are transistors only on one side, to which heat should be diffused.

In the case where as a measure for cooling such heat, thermal vias are formed in a wiring board as disclosed in Japanese Patent Unexamined Publication No. 2-219298, possible in heat distribution inside a semiconductor substrate makes it impossible to ignore a part of heat, which flows in a direction (hereinafter, referred to as “planar direction”) orthogonal to a thickness-wise direction of the semiconductor substrate, in addition to one-dimensional flow of heat in thermal vias, in the event of insufficient diffusion of heat in the semiconductor substrate. That is, when heating areas in the semiconductor substrate are distant from positions of the thermal vias in the planar direction in a wiring board, thermal resistance correspondingly increases.

Also, when radiation paths in a wiring board which mounts a semiconductor substrate is not suitable in the case where via holes and PHS are used as disclosed in Japanese Patent Unexamined Publication No. 5-152340, it is difficult to reduce thermal resistance. In particular, there is a need of making PHS, which an expensive material such as gold plating is used to form, as thin as possible in thickness from a viewpoint of cost reduction. However, when PHS is made thin, diffusion of heat in a PHS layer becomes extremely insufficient in a planar direction, and while thermal diffusion remains insufficient, heat is conducted to a multilayer wiring board via a brazing material. Therefore, when via holes and thermal vias are positionally distant from each other, thermal resistance of the entire wiring board cannot be reduced from a semiconductor device with the result that the via holes and thermal vias cannot serve as radiation paths.

Further, in the case where a semiconductor substrate having a small thermal conductivity like a GaAs substrate is used, and in the case where an insulating film adapted to function as a thermally insulating material is present between a device circuit surface and a substrate mother material like a SOI (silicon on insulator) substrate, there is the possibility that radiation electrodes provided on that surface of the semiconductor substrate, on which a circuit is formed, serve inadequately due to the fact that thermal resistance of paths, along which heat is discharged to the semiconductor substrate and the wiring board from heating areas such as emitter base junctions through wiring and radiation electrodes, becomes larger than that of paths, along which heat is discharged directly to a back surface of the semiconductor substrate from the heating areas, because thermal resistance is increased when heat passes through the semiconductor substrate. In the well-known technique disclosed in Japanese Patent Unexamined Publication No. 8-227896, radiation electrodes are simply formed on a semiconductor substrate with a diffusion layer for contact therebetween, and so such technique cannot be said to be sufficiently effective from a viewpoint of heat radiation in a thickness-wise direction of a semiconductor substrate, a wiring board, or a semiconductor substrate.

In this manner, any conventional technique cannot provide ideal heat radiation.

An object of the present invention is to provide a multilayer wiring board, in which thermal resistance of radiation paths is reduced to provide an improvement in radiation effect.

### SUMMARY OF THE INVENTION

The above object is attained by a multilayer wiring board having through holes in a thickness-wise direction, wherein a semiconductor substrate mounted on the multilayer wiring board has through holes in a thickness-wise direction thereof, and entire areas, which the through holes in the semiconductor substrate occupy, in a plane orthogonal to the thickness-wise direction of the multilayer wiring board and of the semiconductor substrate are included in areas, which the through holes in the multilayer wiring board occupy.

Also, the above object is attained by A multilayer wiring board having through holes in a thickness-wise direction, wherein a semiconductor substrate mounted on the multilayer wiring board has through holes in a thickness-wise direction thereof, and entire areas, which the through holes in the semiconductor substrate occupy, in a plane orthogonal to the thickness-wise direction of the multilayer wiring board and of the semiconductor substrate partly overlap areas which the through holes in the multilayer wiring board occupy.

Also, the above object is attained by A multilayer wiring board having a through hole or holes in a thickness-wise direction, wherein respective heating areas inside a semiconductor substrate mounted on the multilayer wiring board are included in areas, which the single or plural through holes in the multilayer wiring board occupy, in a plane orthogonal to the thickness-wise direction of the multilayer wiring board and of the semiconductor substrate.

Also, the above object is attained by A multilayer wiring board having through holes in a thickness-wise direction, wherein a semiconductor substrate mounted on the multilayer wiring board has through holes in a thickness-wise direction thereof, and heat flow one-dimensionally through the through holes in the semiconductor substrate and the through holes in the multilayer wiring board in the thickness-wise direction when heat flows out to a surface of the multilayer wiring board opposite to that surface thereof, on which the semiconductor substrate is mounted, via the through holes in the semiconductor substrate and the through holes in the multilayer wiring board.

Also, the above object is attained by an arrangement, in which conductive layers are formed on side surfaces of the through holes, or interiors of the through holes comprise a conductive material.

Also, the above object is attained by an arrangement, in which a semiconductor element is mounted, in which conductive layers are formed on side surfaces of the through holes, or interiors of the through holes comprise a conductive material.

Also, the above object is attained by an arrangement, in which wirings, which connect heating areas in the semiconductor substrate mounted on the multilayer wiring board, are electrically connected to the through holes in the semiconductor substrate, and electrical connection is effected through the heating areas, the wirings, the through holes of the semiconductor substrate, the through holes of the multilayer wiring board, and a surface of the multilayer wiring board, on which the semiconductor substrate is not mounted, in this order.

Also, the above object is attained by a multilayer wiring board having through holes in a thickness-wise direction, wherein the distribution density of calorific values in a plane orthogonal to the thickness-wise direction of a semiconductor substrate mounted on the multilayer wiring board substantially coincides with the distribution density in a plane orthogonal to the thickness-wise direction of the through holes.

Also, the above object is attained by a multilayer wiring board having through holes in a thickness-wise direction, wherein the distribution density of calorific values in a plane orthogonal to the thickness-wise direction of a semiconductor substrate mounted on the multilayer wiring board substantially coincides with the distribution density of large and small cross-sectional areas in a plane orthogonal to the thickness-wise direction of the through holes.

Also, the above object is attained by a wiring board, wherein a semiconductor substrate having through holes, which are connected to emitter wirings connected to emitters of heterojunction bipolar transistors and extend through the semiconductor substrate in a thickness-wise direction and which have conductive layers on sides thereof or inside thereof, is mounted on the multilayer wiring board, and the through holes in the semiconductor substrate and the through holes extending through the wiring board in a thickness-wise direction are connected to each other, and wherein conductive layers are provided on sides of or inside of the through holes in the semiconductor substrate and the wiring board, and areas, which the through holes in the semiconductor substrate occupy, in a plane orthogonal to the thickness-wise direction of the multilayer wiring board and of the semiconductor substrate are included in areas, which the through holes in the multilayer wiring board occupy.

Also, the above object is attained by a multilayer wiring board, wherein emitter fingers of heterojunction bipolar transistors are arranged on a semiconductor substrate, the semiconductor substrate is mounted on a wiring board, which has through holes in a thickness-wise direction, and the through holes in the wiring board have on sides or inside thereof a material of good thermal conductivity, and wherein areas, which emitter fingers except emitter fingers at both ends of the emitter fingers electrically connected by the same emitter wirings occupy in a plane orthogonal to the thickness-wise direction of the semiconductor substrate and the wiring board, are included in areas, which the through holes in the wiring board occupy, but areas, which the fingers at the both ends occupy, are not included therein.

Also, the above object is attained by a semiconductor device including a plurality of finger-like emitter electrodes or source electrodes, and at least one via hole arranged in rows in a first direction on a semiconductor substrate, in which semiconductor device the emitter electrodes or the source electrodes are connected to a conductive layer formed on a back surface opposite to that surface, on which the electrodes are formed, through the via hole, and in which semiconductor device rows comprising the emitter electrodes or source electrodes, and the via hole are arranged in parallel in a second direction orthogonal to the first direction, and the via holes are positionally offset from one another among adjacent rows, or adjacent rows are positionally offset from one another.

Also, the above object is attained by an arrangement, in which the multilayer wiring board has through holes formed on sides thereof or inside thereof with a conductive layer, and areas, which the via hole of the semiconductor device occupies, overlap areas, which the through holes of the multilayer wiring board occupy in a plane orthogonal to the thickness-wise direction.

### BRIEF DESCRIPTION OF THE DRAWINGS

FIG. 1 is a cross sectional view of a multilayer wiring board according to the present invention.

FIGS. 2A to 2C are views showing a fundamental embodiment according to the present invention.

FIG. 3 is a cross sectional view showing a semiconductor substrate and a multilayer wiring board in the prior art.

FIG. 4 is a view showing the positional relationship between via holes and thermal vias in a prior semiconductor substrate.

FIG. 5 is a cross sectional view showing an embodiment, in which thermal vias are arranged below heating areas.

FIG. 6 is a cross sectional view showing heat flows in a semiconductor substrate.

FIG. 7 is a cross sectional view showing an embodiment, in which thermal vias are arranged below via holes and heating areas.

FIG. 8 is a cross sectional view showing an embodiment, in which thermal vias are arranged below only central portions of heating areas.

FIG. 9 is a cross sectional view showing an embodiment, in which a circuit surface is formed on a SOI substrate.

FIG. 10 is a cross sectional view showing a typical cross-sectional structure of a prior heterojunction bipolar transistor.

FIG. 11 is a view showing an arrangement of electrodes and via holes in a prior semiconductor substrate.

FIG. 12 is a view showing an embodiment, in which via holes are positionally offset between adjacent rows.

FIG. 13 is a view showing an embodiment, in which rows of emitters are positionally offset between adjacent rows.

FIG. 14 is a view showing an embodiment, in which rows of emitters are positionally offset between adjacent rows and via hoes and thermal vias positionally overlap one another.

### DESCRIPTION OF THE EMBODIMENTS

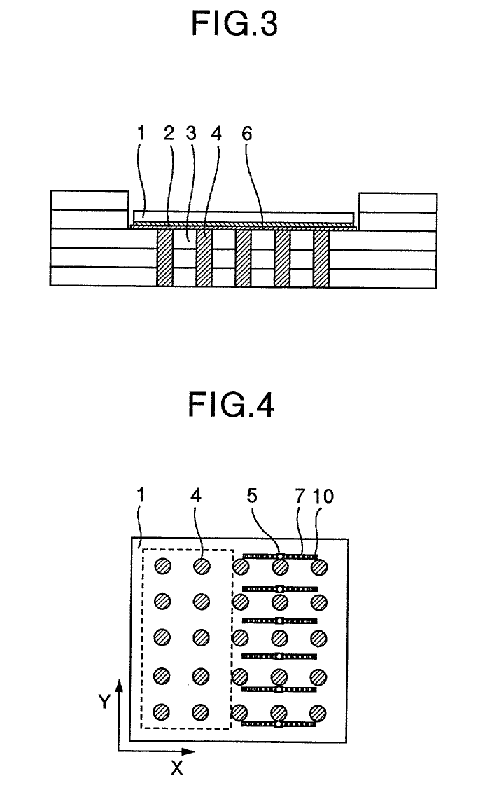

Incidentally, a semiconductor device used in high frequency power amplifiers for pocket communication terminals etc. is constituted conventionally, as shown in FIG. 3, by stacking a multilayer wiring board 3, a brazing material 2, and a semiconductor device 1 in this order from below. In a semiconductor device of such structure, though not shown, a plurality of parts, such as a chip capacitor and a resistor, as well as the above-described semiconductor device 1 are mounted on the wiring substrate 3.

Also, a mother material of the above-described multilayer wiring board 3 is a ceramic-based, a glass-ceramic-based, or a glass-epoxy-based electric insulating material. Generally, there has been caused a problem that since electric insulating materials also have a low thermal conductivity, they in use while in an original state result in an increase in thermal resistance of an entire device and even if a back side of the device is kept at temperature below a certain value, a heating area in the semiconductor device extremely rises in temperature to cause thermorunaway of or breakage, in some cases, of the device.

In order to solve the problem, that technique is adopted, in which a plurality of pillar-shaped members (hereinafter, referred to as “thermal via”) 4 with conductivity and high thermal conductivity are arranged to substantially extend through the multilayer wiring board 3 in a thickness-wise direction, a semiconductor device 1 is mounted thereon by means of a conductive brazing material 2 such as solder, the thermal vias are connected to a common grounding electrode on a mother board from a back side of the multilayer wiring board 3 and thermal connection is also ensured therebetween to reduce thermal resistance between heating areas in the semiconductor device 1 and the back side of the wiring board 3.

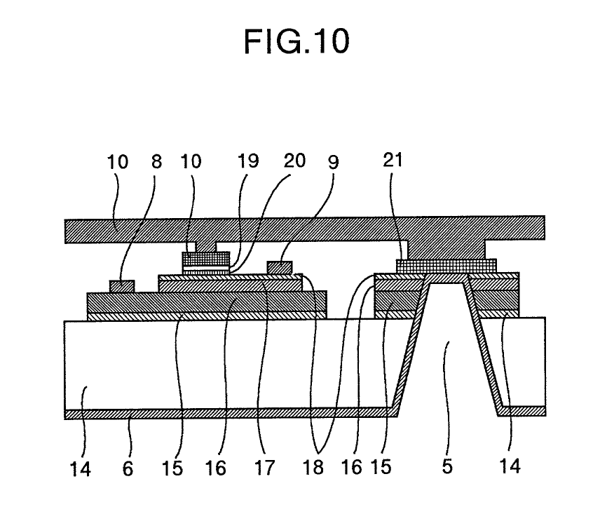

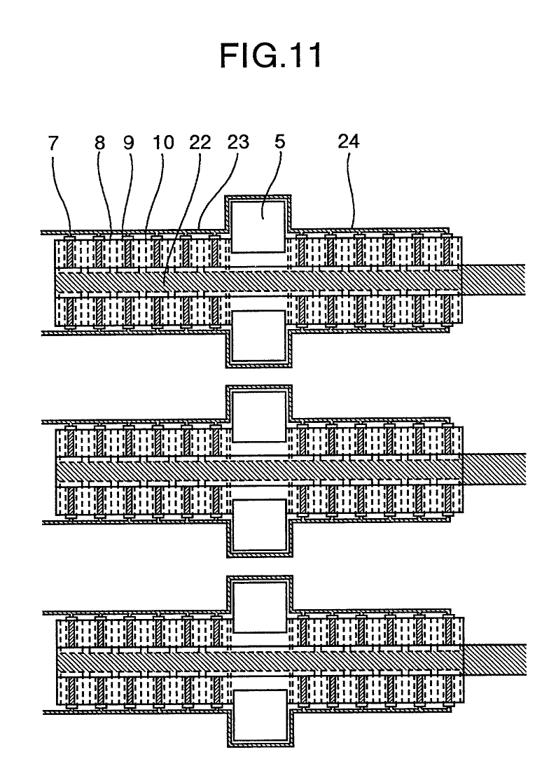

Meanwhile, in order to enhance output and efficiency of the power amplifier, there has been developed a device of the type, in which where hetero-bipolar transistors (HBTs) are formed on a compound semiconductor substrate such as GaAs or the like. FIG. 10 shows an exemplary cross sectional structure of the device and FIG. 11 shows an exemplary plan in the case where a plurality of comb-type finger electrodes are aligned. Such compound semiconductor substrate involves a problem that it has a low thermal conductivity as compared with Si-based substrates, and is insulating except portions, which form semiconductors. Therefore, in the case where a compound semiconductor substrate such as GaAs is used to form a semiconductor device, a technique is adopted, in which thermal resistance between heating areas on a surface of the device and a back side of a wiring board is reduced by providing through holes (hereinafter, referred to as “via hole”) 5 in a portion of the device, providing plated layers such as gold plating on a back surface of the device and on side surfaces of the through holes to thereby electrically connect the front and back surfaces of the device via the via holes 5, and using the plated layers as thermal diffusion plates. Generally, the plated layers used as the thermal diffusion plates are called a plated heat sink (PHS) 6.

Meanwhile, a major part of heat generated in circuits formed on the surface of the semiconductor device 1 spreads in a planar-wise manner and passes through the device in a thickness-wise direction, and diffuses in the PHS 6 in a planar-wise manner to be transmitted to the multilayer wiring board. However, a part of such heat gets to locations distant from the heating areas via a wiring layer on'the surface of the device to enable reducing thermal resistance to some extent.

In particular, a problem of heat radiation in a planar-wise manner exhibits itself markedly as the semiconductor substrate becomes thin. Conventionally, the above problem has not come to the fore since semiconductor substrates are fairly thick to be much effective in planar-wise diffusion of heat within a substrate, and distribution of heat flux is substantially uniform on a back surface of the semiconductor substrate. However, when heating areas in a semiconductor substrate are increased in packaging density and a size in plan becomes small, thermal resistance in thickness-wise direction causes a so much problem, which makes it necessary to make the semiconductor substrate thin and to reduce the thermal resistance.

However, when a semiconductor substrate is made thin, planar-wise diffusion of heat inside of the semiconductor substrate becomes insufficient, and so distribution of heat flux on a back surface of the semiconductor substrate is affected by the calorific value and distribution of heating areas on the front surface of the substrate to lead to an increase thermal resistance in a planar-wise direction unless heat thermal conductive members such as thermal vias are arranged in appropriate positions. Thus, a problem is caused that thermal resistance is not reduced though the substrate is made thin.

Meanwhile, in designing arrangement of electrodes and via holes 5 in a plane where circuits of a semiconductor device are formed, it has been conventionally general to align rows of electrodes in position in the case where, as shown in FIG. 11, a plurality of rows of electrodes are connected in parallel to function as one semiconductor element. With such arrangement, irrespective of whether via holes 5 are arranged in a center or ends of the rows of electrodes, the via holes 5 are arranged substantially in a line in a longitudinal direction in the figure. Moreover, when the number of the electrodes in the respective rows of electrodes involves no scatter, positions of the electrodes will be also arranged substantially in a line in a longitudinal direction in the figure. However, such arrangement presents the following issues.

Here, it is assumed that heating areas are mainly constituted by emitter base junctions disposed below emitter electrodes 7. In the case of an arrangement in a cross sectional view shown in FIG. 10, a heating area is in the vicinity of near a junction of a highly doped p type GaAs base layer 18 and a highly doped n type InGaP emitter layer 20. As described above, heat generated in this area is discharged in a thickness-wise direction of a semiconductor substrate 1 while diffusing in longitudinal and transverse directions in FIG. 11. However, when fingers are laid down as shown in FIG. 11, via holes and ends of rows of electrodes are aligned in position, which causes a problem that fingers arranged in positions distant from the via holes and from the ends of rows of electrodes are restricted in radiation paths to become liable to rise in temperature.

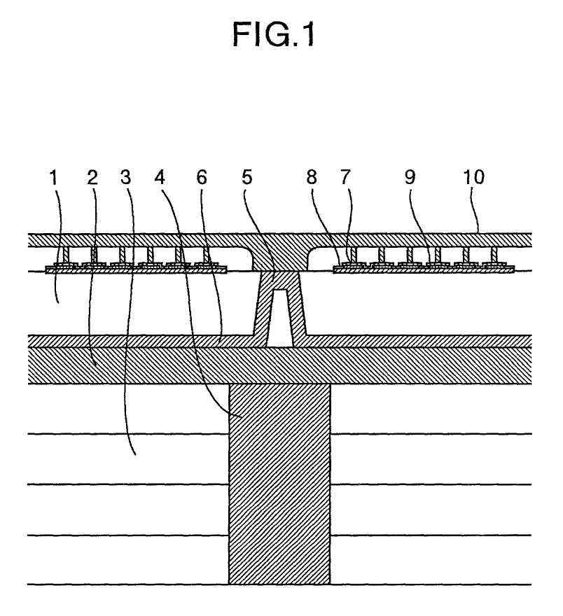

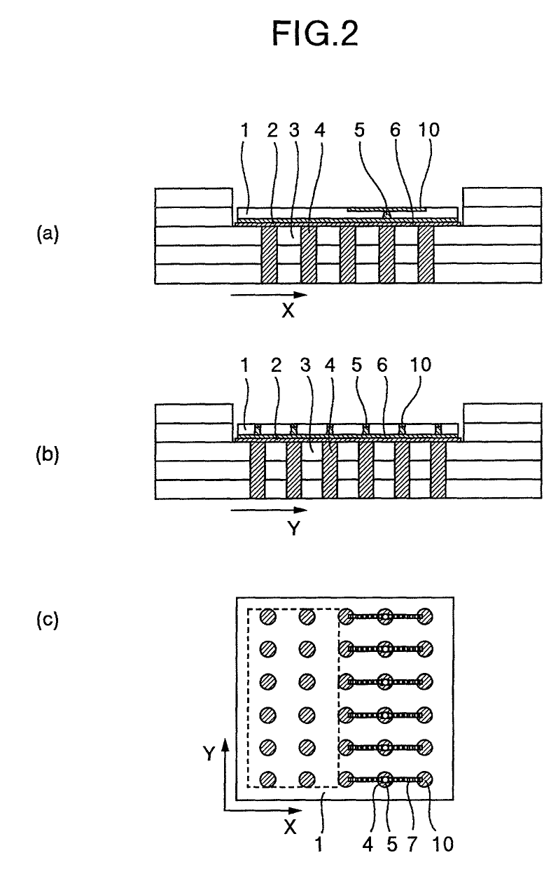

Hereafter, an embodiment of the present invention will be described with reference to FIGS. 1 and 2.

FIG. 1 is a cross sectional view showing the positional relationship between a multilayer wiring board according to the present invention and a semiconductor substrate mounted thereon. In addition, FIG. 1 shows a typical case where a material of the semiconductor substrate 1 is GaAs and circuits are heterojunction bipolar transistors (hereinafter, referred to as “HBT”). However, it goes without saying that a material of the semiconductor substrate 1 is not limited to GaAs, and the circuits are not limited to the HBTs.

FIGS. 2A to 2C are views showing, in cross section containing an entire semiconductor substrate, the positional relationship between a multilayer wiring board and a semiconductor substrate. Thus, FIG. 2A is a cross sectional view in a X direction, FIG. 2B is a cross sectional view in a Y direction, and FIG. 2C is a plan. In addition, while there is no specific limitation on determination of the X and Y directions, it is assumed here that the semiconductor substrate is rectangular in a planar direction and that the X direction is parallel to one side of the rectangle and the Y direction is orthogonal to the X direction.

In FIG. 1, a plurality of emitter electrodes 7 are arranged in rows shown in FIG. 2C, collector electrodes 8 are arranged between the adjacent emitter electrodes 7 in a row, and base electrodes 9 are formed in a manner to sandwich individual emitter electrodes 7 therebetween. It is defined relative to the thickness-wise direction of the semiconductor substrate 1 that a side contacting the PHS 6 is lower, and a side, on which a circuit surface is formed, is upper. At this time, the emitter electrodes 7 and the emitter wirings 10 are-shown in the structure shown in FIGS. 1 and 2. However, constituent members such as collector wiring, base wiring, other circuit parts, wire pads and so on are omitted for the purpose of simplification.

Emitter electrodes 7 are connected to emitter wirings 10 in FIG. 1 and FIG. 2. In addition, the emitter wirings 10 are connected to the via holes 5 provided in the semiconductor substrate. Side surfaces of the via holes 5 are covered with a material, which is the same as that of the PHS 6 and has good thermal and electrical conductivity, or interiors of the via holes 5 are filled with a material, which has good thermal and electrical conductivity. In the case where the semiconductor substrate 1 is formed of an electrically conductive material, it is desired that the above-described processing is performed after an insulating film is formed on the surfaces of the via holes 5. Also, the semiconductor substrate 1 is mounted on the multilayer wiring board 3 through a brazing material 2 such as solder and an electrically conductive adhesive. In addition, while the wiring board 3 is multilayered here, the present inventions is applicable even to a single-layer wiring board, which has wiring patterns on upper and lower sides thereof.

Thermal vias 4 are arranged on the multilayer wiring board 3. Similarly to the via holes 5, side surfaces of the thermal vias 4 are formed with a layer of a material, which is thermally and electrically conductive, or interiors of the thermal vias 4 are filled with a material, which is thermally and electrically conductive. In the present invention, an entire area occupied by the via holes 5 is included in an area occupied by the thermal vias 4 in the XY plane in the figure. Therefore, when heat loss generated in emitter base junctions in the vicinity of the emitter electrodes 7 is discharged to a back surface of the multilayer wiring board 3 via the emitter wirings 10 and via holes 5, discharge of heat is effected one-dimensionally in a thickness-wise direction through the via holes 5, brazing material 2, and thermal vias 4 in this order in the semiconductor substrate 1. Accordingly, there is no need of heat transmission in a planar direction in, for example, the PHS layer 6 and the brazing material 2, and so it is possible to efficiently discharge heat loss, generated in the emitter base junctions in the vicinity of the emitter electrodes 7, to an underside of the multilayer wiring board 3, and to discharge heat outside of the substrate.

As mentioned above, FIGS. 3 and 4 are views showing an exemplary arrangement of a conventional semiconductor substrate 1 and a multilayer wiring board 3, in which the positional relationship between the thermal vias 4 and via holes 5 is not prescribed. Therefore, there is caused a problem that as shown in plan in FIG. 4, the via holes 5 and thermal vias 4 get out of position relative to each other, and though the multilayer wiring board 3 has thermal resistance as an element equivalent to that of the embodiment of the present invention shown in FIGS. 1 and 2, thermal resistance of the entire structure is increased in terms of radiation paths in the planar direction.

However, in the case where the number of the via holes 5 is plural as shown in FIG. 2, the number of the thermal vias 4 may also be plural. Even if the number of the thermal vias 4 is one as a whole, or one for each via hole 5, or one for a plurality of via holes 5, the same effect can be achieved in any one of the above cases so long as that condition is met, in which an entire area occupied by the via holes 5 is included in an area occupied by the thermal vias 4 in the XY plane in the figure. Also, while FIG. 2 shows an arrangement, in which the thermal vias 4 are regularly arranges outside the area occupied by the thermal vias 4, the thermal vias 4 are free in cross section, shape, number, and arrangement provided that the above-mentioned condition is met. So, without other circuit components having large heat loss, it does not matter if any thermal vias 4 are not arranged elsewhere. On the contrary, when there are other circuit components with large calorific values, thermal vias 4 may be separately provided below the circuit components.

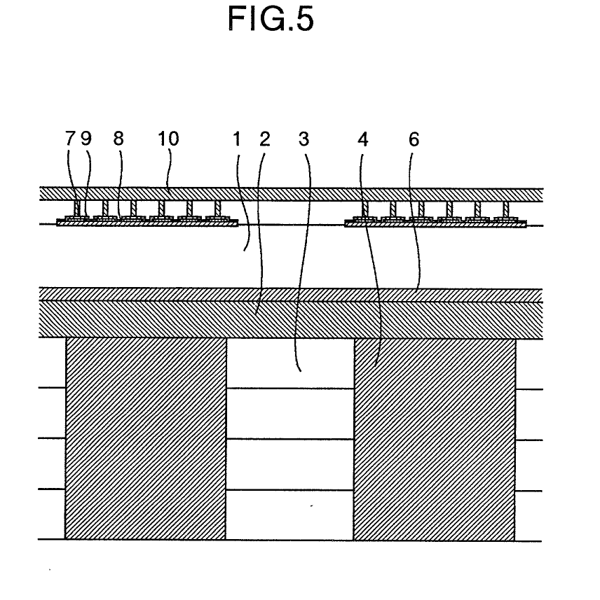

A further embodiment of the present invention will be described with reference to FIG. 5. FIG. 5 is a cross sectional view showing the positional relationship between a multilayer wiring board and a semiconductor substrate mounted thereon in this embodiment. In addition, the same numerals as those in FIGS. 1 and 2 designate the same parts or elements as those in the figures, and so an explanation therefor will be omitted.

In this embodiment, an area, in which emitter electrodes 7 is arranged, is included in an area occupied by via holes 4 in a XY plane.

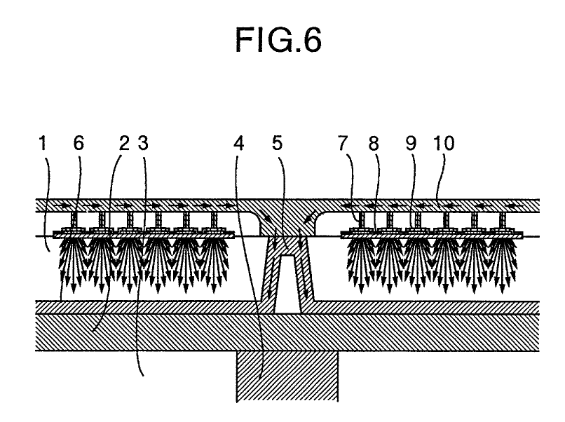

FIG. 6 is a schematic diagram showing radiation paths in a cross section in the embodiment of the present invention shown in FIGS. 1 and 2. Heat generated in respective emitter base junctions is mainly divided into a part that goes from the emitter wirings 10 to the underside of the multilayer wiring board 3 via the via holes 5 and thermal vias 4, and a part that directly goes to the underside of the semiconductor substrate 3 not through the emitter wirings 10 while diffusing in the XY directions, and flows in the XY directions in the inerior of the multilayer wiring board 3 or in the PHS 6 and the brazing material 2. While heat is finally discharged outside due to heat conduction or heat transmission, thermal resistance of the thermal vias 4 and thermal resistance of only the multilayer wiring board 3a form a thermally parallel circuit so that a major part of heat passes through the thermal vias 4 and a part of heat passes through the multilayer wiring board 3 in the thickness-wise direction. The smaller the thermal conductivity of the mother material of the multilayer wiring board 3 is, the larger an amount of heat passing through the thermal vias 4 becomes.

In the embodiment of the present invention shown in FIG. 5, an area, in which the emitter electrodes 7 are arranged, is included in an area occupied by the thermal vias 4 in the XY plane, so that heat going to an underside of the device not through the emitter wirings 10 does not flow in the XY directions, but flows into the thermal vias 4 in a one-dimensional manner. Therefore, it is possible to reduce the total thermal resistance.

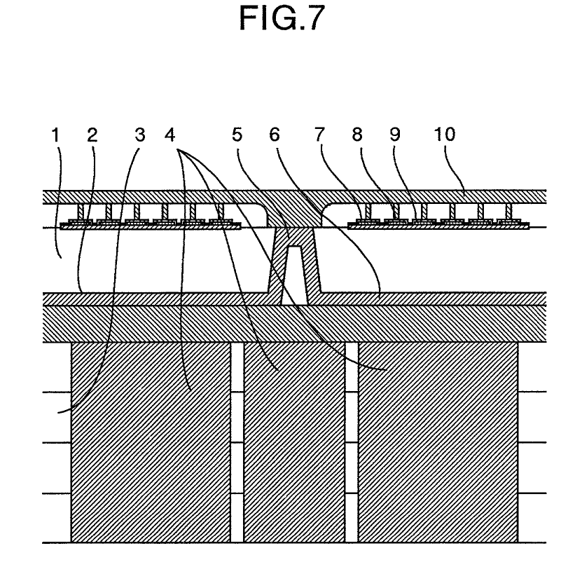

A still further embodiment of the present invention is shown in FIG. 7. This embodiment has a feature in that areas, in which via holes 5 and emitter electrodes 7 are arranged, respectively, are included in an area occupied by thermal vias 4 in a XY plane. Therefore, heat loss generated in emitter base junctions in the vicinity of the emitter electrodes 7 comprises a part passing through the emitter wiring 10 and via hole 5 and a part that directly goes to the underside of the semiconductor substrate 1 while diffusing in the XY directions, the both parts flowing into the thermal vias 4 in a one-dimensional manner, thereby enabling reducing the total thermal resistance from the heating areas to the underside of the multilayer wiring board 3.

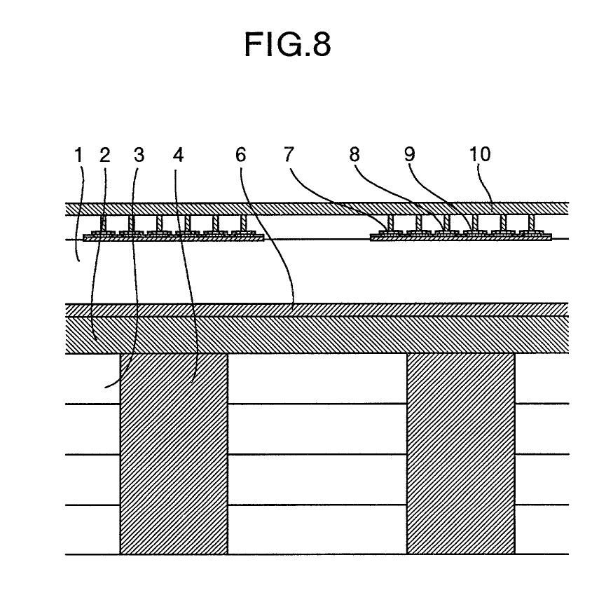

A further embodiment of the present invention is shown in FIG. 8. The embodiment shown in FIG. 8 is substantially the same as that shown in FIG. 5 but is constructed such that thermal vias 4 are not arranged only below emitter electrodes disposed nearest to ends (chip ends in the figure) of the semiconductor substrate 1. When a plurality of emitter electrodes 7 are arranged in rows on the semiconductor substrate 3, temperature of emitter base junctions in the vicinity of the respective emitter electrodes 7 is such that a plurality of emitters are high in temperature for those close to centers of the emitters thus arranged and low in temperature for those in peripheral portions thereof. With a high frequency element such as a power amplifier for portable phones, there is the need of making temperature distribution as uniform as possible because in particular, when HBTs are mounted, scatter in temperature of respective emitters arranged in parallel causes scatter in current flowing through the respective emitters to have the possibility that positive feedback is applied to cause oscillation of elements and eventual breakage thereof.

To meet such need, an arrangement is preferable, in which thermal vias 4 are arranged immediately below those ones disposed centrally of emitters thus arranged, but not arranged immediately below the emitters in the peripheral portions. As a result, it is possible to preserve thermal resistance of the emitters in the peripheral portions as it is, and to decrease only thermal resistance of ones disposed centrally of emitters thus arranged, so that it is possible to reduce scatter in temperature as well as to reduce the entire thermal resistance.

In addition, the cross sectional views shown in FIGS. 1, 5, 7, and 8 depict arrangements, in which a single thermal via 4 is allotted to a single via hole 5 and a single thermal via 4 is allotted to six emitter electrodes 7, respectively. However, the thermal vias 4 are free in number, size, and way of arrangement so long as the conditions prescribed in the respective embodiments are met, and so a singe thermal via 4 may be allotted to a plurality of via holes 5 or one-to-one correspondence may be applied. Also, a singe thermal via 4 may be allotted to a plurality of emitter electrodes 7 or one-to-one correspondence may be applied. Further, FIG. 5 shows an arrangement, in which the emitter electrodes 7 are divided into two groups though there is no showing of any via hole 5. However, it does not matter if the emitter electrodes are divided into a plurality of groups, or arranged individually according to a certain rule.

Also, cross sectional views or plan views showing the respective embodiments of the present invention shown in FIGS. 1, 2, 4, and 7 show arrangements, in which only one via hole 5 per row is provided centrally of a row of the emitter electrodes 7 connected to one another by a line of emitter wiring 10. However, the number and arrangement of the via holes 5 are optional for a row of a plurality of emitter electrodes 7 connected to one another by a line of emitter wiring 10, and so it does not matter if one via hole 5 is arranged at both ends of the row, and a plurality of via holes are arranged in the row.

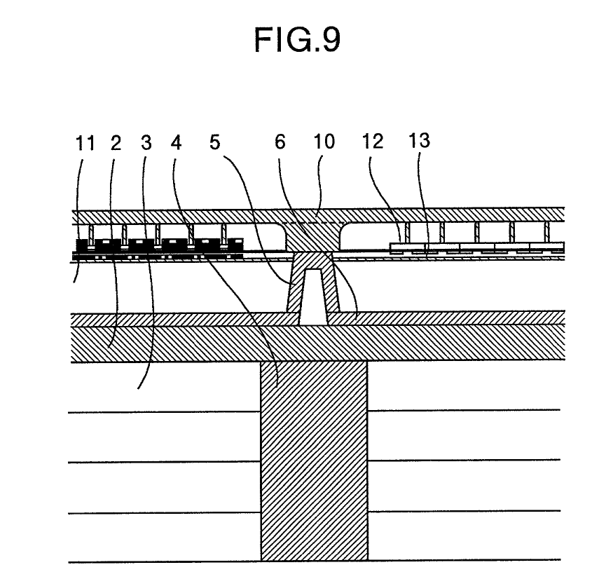

FIG. 9 shows a constitution of a further embodiment of the present invention. In this embodiment, emitter fingers 7 are mounted on a SOI (silicon on insulator) substrate 11. With the SOI substrate, individual transistors 12 are enclosed by an insulating film 13 so as to reduce a parasitic capacitance, with the result that the insulating film 13 causes areas occupied by the respective emitter electrodes 7 to be thermally insulated from one another. With such arrangement, other portions than layers such as emitter wirings 10 cannot serve as a radiation path, so that heat loss generated passes the semiconductor substrate 1 via the emitter wirings 10 and the via holes 5. With such arrangement, areas occupied by the via holes 5 are made to be included in areas occupied by thermal vias 4 in the XY plane, so that it is still more possible to promote heat conduction in the thickness-wise direction and to reduce thermal resistance from the heating areas to the underside of the multilayer wiring board 3.

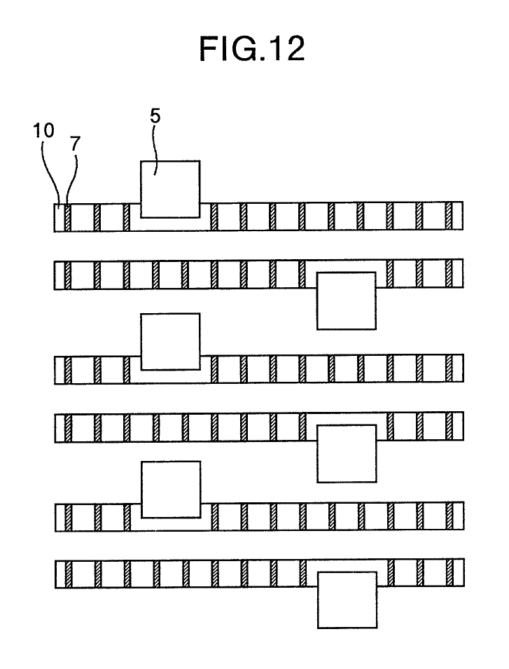

A still further embodiment of the present invention is shown in FIG. 12. FIG. 12 shows the positional relationship among emitter electrodes, emitter wirings, and via holes in this embodiment. In this embodiment, via holes 5 are arranged in positions offset from one another in adjacent rows of emitters. In the case of the arrangement in a conventional semiconductor device shown in FIG. 11, positions of the third and fourth emitter electrodes 7 from the left in the figure and the third and fourth emitter electrodes 7 from the right in the figure are distant from the via holes 5 and also from ends of rows of emitters, thus causing a problem that adequate radiation paths cannot be ensured and so temperature is liable to rise. However, the arrangement shown in FIG. 12 makes it possible to reduce a distance from an emitter electrode 7 to the via holes 5 arranged in not a row, to which the emitter electrode 7 concerned is connected, but adjacent rows, whereby emitter electrodes 7 having been liable to rise in temperature with a conventional semiconductor device decrease in temperature, making it possible to maintain temperature distribution constant and to reduce thermal resistance of the entire semiconductor device.

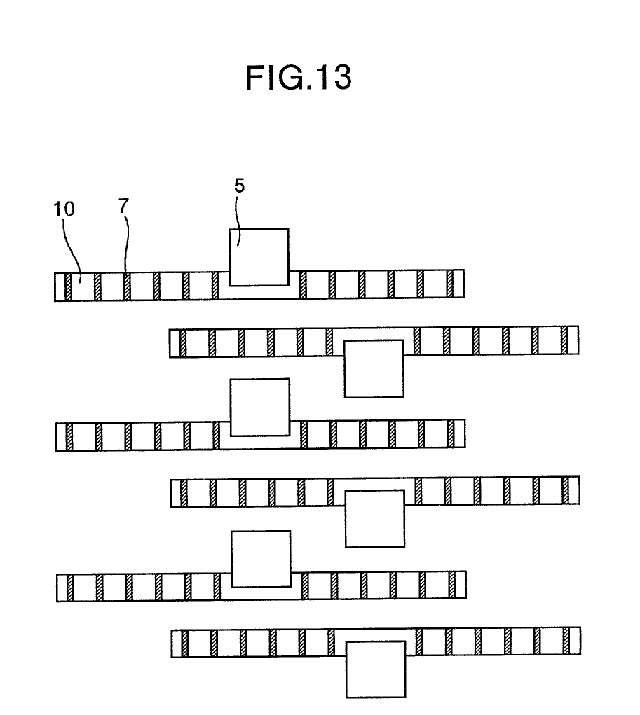

A still another embodiment of the present invention is shown in FIG. 13. FIG. 13 shows the positional relationship among emitter electrodes, emitter wirings, and via holes in this embodiment. Rows of emitters themselves are positionally offset from adjacent rows in this embodiment, and so the via holes 5 are also arranged offset from those in adjacent rows. As a result, heat generated in emitter fingers 7 disposed near ends of rows can be improved in performance of radiation since portions free of heating areas are present in the periphery. Also, heat generated in the emitter fingers 7 distant from ends of rows and also from the via holes 5 in the rows can be improved in performance of radiation of heat discharged to the via holes 5 in the adjacent rows.

In addition, while positions of the via holes 5 and rows of fingers are periodically offset from one another in the embodiment of the present invention shown in FIGS. 12 and 13, the present invention has no reason for such periodicity in the way of such offsetting, and so it goes without saying that the same effect can be obtained in that arrangement, in which heating areas in the respective emitter fingers are constant in temperature distribution and temperature is decreased as compared with the case where no countermeasure is adopted, though such arrangement deviates somewhat in periodicity.

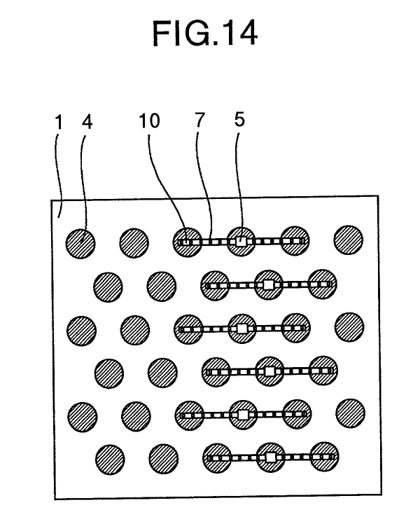

A further embodiment of the present invention is shown in FIG. 14. FIG. 14 shows the arrangement of heating areas in the semiconductor substrate 1 and of thermal vias in the multilayer wiring board 3. Thus, this embodiment is obtained by a combination of the embodiment of the present invention shown in FIG. 1 and the embodiment of the present invention shown in FIGS. 12 and 13. Such arrangement of heating areas, via holes and thermal vias makes it possible to achieve further reduction of thermal resistance.

In this manner, it is possible according to the present invention to reduce thermal resistance of an entire device, since heat generated in respective heating areas can be effectively conducted to an underside of a multilayer wiring board. Also, since heat generated in respective heating areas can be effectively let out to via holes and a semiconductor substrate, thermal resistance of an entire device can be reduced.

It is possible according to the present invention to provide a multilayer wiring board improved in radiation effect, since radiation paths leading from emitter wirings to an underside of a multilayer wiring board through via holes and thermal vias can be reduced in thermal resistance.

1. A multilayer wiring board having through holes in a thickness-wise direction,
wherein a semiconductor substrate mounted on the multilayer wiring board has through holes in a thickness-wise direction thereof, and entire areas, which the through holes in the semiconductor substrate occupy, in a plane orthogonal to the thickness-wise direction of the multilayer wiring board and of the semiconductor substrate are included in areas, which the through holes in the multilayer wiring board occupy.

2. A multilayer wiring board having through holes in a thickness-wise direction,
wherein a semiconductor substrate mounted on the multilayer wiring board has through holes in a thickness-wise direction thereof, and entire areas, which the through holes in the semiconductor substrate occupy, in a plane orthogonal to the thickness-wise direction of the multilayer wiring board and of the semiconductor substrate partly overlap areas which the through holes in the multilayer wiring board occupy.

3. A multilayer wiring board having a through hole or holes in a thickness-wise direction, wherein respective heating areas inside a semiconductor substrate mounted on the multilayer wiring board are included in areas, which the single or plural through holes in the multilayer wiring board occupy, in a plane orthogonal to the thickness-wise direction of the multilayer wiring board and of the semiconductor substrate.

4. A multilayer wiring board having through holes in a thickness-wise direction,
wherein a semiconductor substrate mounted on the multilayer wiring board has through holes in a thickness-wise direction thereof, and heat flow one-dimensionally through the through holes in the semiconductor substrate and the through holes in the multilayer wiring board in the thickness-wise direction when heat flows out to a surface of the multilayer wiring board opposite to that surface thereof, on which the semiconductor substrate is mounted, via the through holes in the semiconductor substrate and the through holes in the multilayer wiring board.

5. The multilayer wiring board according to one of claims 1 to 3, wherein conductive layers are formed on side surfaces of the through holes, or interiors of the through holes comprise a conductive material.

6. The multilayer wiring board according to one of claims 1 to 3, wherein a semiconductor element is mounted, in which conductive layers are formed on side surfaces of the through holes, or interiors of the through holes comprise a conductive material.

7. The multilayer wiring board according to claim 1, wherein wirings, which connect heating areas in the semiconductor substrate mounted on the multilayer wiring board, are electrically connected to the through holes in the semiconductor substrate, and electrical connection is effected through the heating areas, the wirings, the through holes of the semiconductor substrate, the through holes of the multilayer wiring board, and a surface of the multilayer wiring board, on which the semiconductor substrate is not mounted, in this order.

8. A multilayer wiring board having through holes in a thickness-wise direction,
wherein the distribution density of calorific values in a plane orthogonal to the thickness-wise direction of a semiconductor substrate mounted on the multilayer wiring board substantially coincides with the distribution density in a plane orthogonal to the thickness-wise direction of the through holes.

9. A multilayer wiring board having through holes in a thickness-wise direction,
wherein the distribution density of calorific values in a plane orthogonal to the thickness-wise direction of a semiconductor substrate mounted on the multilayer wiring board substantially coincides with the distribution density of large and small cross-sectional areas in a plane orthogonal to the thickness-wise direction of the through holes.

10. A wiring board,
wherein a semiconductor substrate having through holes, which are connected to emitter wirings connected to emitters of heterojunction bipolar transistors and extend through the semiconductor substrate in a thickness-wise direction and which have conductive layers on sides thereof or inside thereof, is mounted on the multilayer wiring board, and the through holes in the semiconductor substrate and the through holes extending through the wiring board in a thickness-wise direction are connected to each other, and wherein conductive layers are provided on sides of or inside of the through holes in the semiconductor substrate and the wiring board, and areas, which the through holes in the semiconductor substrate occupy, in a plane orthogonal to the thickness-wise direction of the multilayer wiring board and of the semiconductor substrate are included in areas, which the through holes in the multilayer wiring board occupy.

11. A multilayer wiring board,
wherein emitter fingers of heterojunction bipolar transistors are arranged on a semiconductor substrate, the semiconductor substrate is mounted on a wiring board, which has through holes in a thicknesswise direction, and the through holes in the wiring board have on sides or inside thereof a material of good thermal conductivity, and wherein areas, which emitter fingers except emitter fingers at both ends of the emitter fingers electrically connected by the same emitter wirings occupy in a plane orthogonal to the thickness-wise direction of the semiconductor substrate and the wiring board, are included in areas, which the through holes in the wiring board occupy, but areas, which the fingers at the both ends occupy, are not included therein.

12. A semiconductor device including a plurality of finger-like emitter electrodes or source electrodes, and at least one via hole arranged in rows in a first direction on a semiconductor substrate, in which semiconductor device the emitter electrodes or the source electrodes are connected to a conductive layer formed on a back surface opposite to that surface, on which the electrodes are formed, through the via hole, and in which semiconductor device rows comprising the emitter electrodes or source electrodes, and the via hole are arranged in parallel in a second direction orthogonal to the first direction, and the via holes are positionally offset from one another among adjacent rows, or adjacent rows are positionally offset from one another.

13. The semiconductor device according to claim 12, wherein the multilayer wiring board has through holes formed on sides thereof or inside thereof with a conductive layer, and areas, which the via hole of the semiconductor device occupies, overlap areas, which the through holes of the multilayer wiring board occupy in a plane orthogonal to the thickness-wise direction.
